(19) United States
(12) Patent Application Publication
(10) Pub. No.: US 2024/0122009 A1
(43) Pub. Date: Apr. 11, 2024

(54) DISPLAY PANEL AND DISPLAY APPARATUS INCLUDING THE SAME

(71) Applicant: Samsung Display Co., LTD., Yongin-si (KR)

(72) Inventors: Seonyoung CHOI, Yongin-si (KR); Bonyong KOO, Yongin-si (KR)

(21) Appl. No.: 18/368,169

(22) Filed: Sep. 14, 2023

(30) Foreign Application Priority Data
Oct. 5, 2022 (KR) 10-2022-0127395

(51) Int. Cl. H10K 59/131

(52) U.S. Cl. CPC H10K 59/131; H10K 2102/311

(57) ABSTRACT

A display panel includes a substrate including a display area and a peripheral area surrounding the display area, a display element arranged in the display area on the substrate, a voltage supply line arranged in the peripheral area on the substrate, where the voltage supply line is electrically connected to a portion of a common electrode of the display element extending to the peripheral area, and a conductive line embedded in the substrate and connected to the voltage supply line.

This application claims priority to Korean Patent Application No. 10-2022-0127395, filed on Oct. 5, 2022, and all the benefits accruing therefrom under 35 U.S.C. § 119, the content of which in its entirety is herein incorporated by reference.

### BACKGROUND

### 1. Field

One or more embodiments relate to a display panel and a display apparatus including the display panel.

### 2. Description of the Related Art

With the rapid development in the field of displays that visually display various electrical signal information, various display apparatuses having desired characteristics, such as thin thickness, lighter weight, and low power consumption, have been introduced. In addition, physical buttons or the like have been recently removed from a front surface of a display apparatus, and thus, a dead area of the display apparatus has decreased, and a display area of the display apparatus has increased.

### SUMMARY

One or more embodiments provide a display apparatus in which a dead area is reduced.

According to one or more embodiments, a display panel includes a substrate including a display area and a peripheral area surrounding the display area, a display element arranged in the display area on the substrate, a voltage supply line arranged in the peripheral area on the substrate, where the voltage supply line is electrically connected to a portion of a common electrode of the display element extending to the peripheral area, and a conductive line embedded in the substrate and connected to the voltage supply line.

According to an embodiment, the conductive line may overlap the voltage supply line and be electrically connected to the voltage supply line via a plurality of contact areas.

According to an embodiment, the substrate may include a first base layer, a second base layer on the first base layer, and a barrier layer between the first base layer and the second base layer, where the barrier layer may include a first barrier layer and a second barrier layer, and the conductive line may be between the first barrier layer and the second barrier layer.

According to an embodiment, the conductive line may surround the display area and be arranged in the peripheral area, a pad area may be defined in the peripheral area, and a portion of the conductive line positioned in the pad area may be connected to a flexible printed circuit board disposed on a rear surface of the substrate.

According to an embodiment, the conductive line may include a first portion and a second portion, the second portion may be positioned farther from the pad area than the first portion, and a width of the second portion of the conductive line may be greater than a width of the first portion.

According to an embodiment, the conductive line may include a first portion and a second portion, where the second portion may be positioned farther from the pad area than the first portion, the conductive line may be electrically connected to the voltage supply line via a plurality of contact areas, and a number of the contact areas per unit length in the first portion of the conductive line may be greater than a number of the contact areas per unit length in the second portion of the conductive line.

According to an embodiment, the conductive line may include a first conductive line and a second conductive line, where the first conductive line may surround the display area and may be arranged in the peripheral area, and the second conductive line extending from the first conductive line to cross the display area, a pad area may be defined in the display area or the peripheral area, and a portion of the second conductive line positioned in the pad area may be connected to a flexible printed circuit board disposed on a rear surface of the substrate.

According to an embodiment, the voltage supply line may include a first supply line and a second supply line, and the second supply line may overlap the first supply line and be in contact with the first supply line.

According to an embodiment, the display panel may further include a first fan-out line arranged in the peripheral area on the substrate and connected to a data line of the display area, and a second fan-out line arranged on a same layer as the conductive line and electrically connected to the first fan-out line.

According to an embodiment, the substrate may include a first base layer, a second base layer on the first base layer, and a barrier layer between the first base layer and the second base layer, where the barrier layer may include a first barrier layer and a second barrier layer, the conductive line may be between the first barrier layer and the second barrier layer, an opening corresponding to a pad area may be defined in the first barrier layer and the first base layer of the substrate, and a portion of the second fan-out line positioned in the pad area may be may be connected to the first fan-out line and a flexible printed circuit board disposed on a rear surface of the substrate.

According to one or more embodiments, a display apparatus includes a display panel in which a display area and a peripheral area surrounding the display area are defined, and an integrated circuit disposed on a rear surface of the display panel, wherein the display panel may include a substrate, a display element arranged in the display area on the substrate, a voltage supply line arranged in the peripheral area on the substrate, wherein the voltage supply line is electrically connected to a portion of a common electrode of the display element extending to the peripheral area, and a conductive line embedded in the substrate and connected to the voltage supply line.

According to an embodiment, the conductive line may overlap the voltage supply line and be electrically connected to the voltage supply line in a plurality of contact areas.

According to an embodiment, the substrate may include a first base layer, a second base layer on the first base layer, and a barrier layer between the first base layer and the second base layer, where the barrier layer may include a first barrier layer and a second barrier layer, and the conductive line may be between the first barrier layer and the second barrier layer.

According to an embodiment, an opening corresponding to a pad area may be defined in the first base layer of the substrate, and the integrated circuit may be mounted on a flexible printed circuit board, a portion of which is disposed in the opening.

According to an embodiment, the conductive line may surround the display area and be arranged in the peripheral area, a pad area may be defined in the peripheral area, where a trench may be defined in the rear surface of the substrate, the trench exposes a portion of the conductive line arranged in the pad area, and a portion of the conductive line may be connected to a portion of a flexible printed circuit board disposed in the trench.

According to an embodiment, the conductive line may include a first portion and a second portion, the second portion may be positioned farther from the pad area than the first portion, and a width of the second portion of the conductive line may be greater than a width of the first portion.

According to an embodiment, the conductive line may include a first portion and a second portion, where the second portion may be positioned farther from the at least one pad area than the first portion, the conductive line may be electrically connected to the voltage supply line via a plurality of contact areas, and a number of the contact area per unit length in the first portion of the conductive line may be greater than a number of the contact areas per unit length in the second portion of the conductive line.

According to an embodiment, the conductive line may include a first conductive line and a second conductive line, where the first conductive line may surround the display area and be arranged in the peripheral area, and the second conductive line may extend from the first conductive line to cross the display area, a pad area may be defined in the display area or the peripheral area, a trench may be defined in the rear surface of the substrate, the trench may expose a portion of the second conductive line arranged in the pad area, and the portion of the second conductive line may be connected to a portion of a flexible printed circuit board disposed in the trench.

According to an embodiment, the voltage supply line may include a first supply line and a second supply line, where the second supply line may overlap the first supply line and be in contact with the first supply line.

According to an embodiment, the display apparatus may further include a first fan-out line arranged in the peripheral area on the substrate and connected to a data line of the display area, and a second fan-out line disposed in a same layer as the conductive line and electrically connected to the first fan-out line.

### BRIEF DESCRIPTION OF THE DRAWINGS

The above and other features of embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a cross-section of a display apparatus, taken along line I-I′ of FIG. 1;

FIG. 3 is a schematic plan view of an area of a display apparatus of FIG. 1;

FIG. 4 is a schematic cross-sectional view of a cross-section of a display panel, taken along line II-II′ of FIG. 3;

FIG. 5 is a schematic diagram showing a conductive line according to an embodiment;

FIG. 6 is a schematic diagram showing a common voltage supply line according to an embodiment;

FIGS. 7A, 7B and 8 are schematic cross-sectional views of cross-sections of a conductive line and a common voltage supply line, taken along lines IIIa-IIIa′ and IIIb-IIIb′ of FIGS. 5 and 6, respectively;

FIGS. 9A, 9B and 10 are schematic cross-sectional views of cross-sections of a conductive line and a common voltage supply line, taken along lines IVa-IVa′ and IVb-IVb′ of FIGS. 5 and 6, respectively;

FIGS. 11A and 11B are diagrams showing a width of a third supply line, according to an embodiment;

FIGS. 12 and 13 are diagrams showing a third supply line and a pad area, according to alternative embodiments; and

FIGS. 14 to 16 are equivalent circuit diagrams of a pixel according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

“Or” as used herein means “and/or.” As used herein, the term “and/or” includes any and all combinations of one or more of the associated listed items. Throughout the disclosure, the expression “at least one of a, b, or c” or “at least one selected from a, b, and c” indicates only a, only b, only c, both a and b, both a and c, both b and c, all of a, b, and c, or variations thereof.

It will be understood that although terms such as “first” and “second” may be used herein to describe various elements, these elements should not be limited by these terms and these terms are only used to distinguish one element from another element. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.”

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

Sizes of elements in the drawings may be exaggerated for convenience of explanation. For example, because sizes and thicknesses of elements in the drawings are arbitrarily illustrated for convenience of explanation, one or more embodiments are not limited thereto.

In the following embodiments, the expression “a line extends in a first direction or a second direction” may include a case in which “a line extends in a linear shape” and a case in which “a line extends in a zigzag or curved shape in a first direction or a second direction.”

In the following embodiments, when an element is referred to as being “in a plan view,” it is understood that the element is viewed from the top, and when an element is referred to as being “in a cross-sectional view,” it is understood that the element is vertically cut and viewed from the side. In the following embodiments, when elements “overlap” each other, the elements overlap “in a plan view” and “in a cross-sectional view.”

In the following embodiments, the x-axis, the y-axis and the z-axis are not limited to three axes of the rectangular coordinate system, and may be interpreted in a broader sense. For example, the x axis, the y axis, and the z axis may be perpendicular to one another or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

When a certain embodiment may be implemented differently, a specific process order may be performed in the order different from the described order. For example, two processes that are successively described may be performed substantially simultaneously or performed in the order opposite to the order described.

In the detailed description and the appended claims of the disclosure, the term “corresponding” is used to specify elements arranged in the same area among a plurality of elements depending on the context. For example, when a first element corresponds to a second element, it may mean that the second element is arranged in the same area as the first element.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail by referring to the accompanying drawings. In descriptions with reference to the drawings, the same reference numerals are given to elements that are the same or substantially the same as each other and any repetitive detailed descriptions thereof may be omitted or simplified.

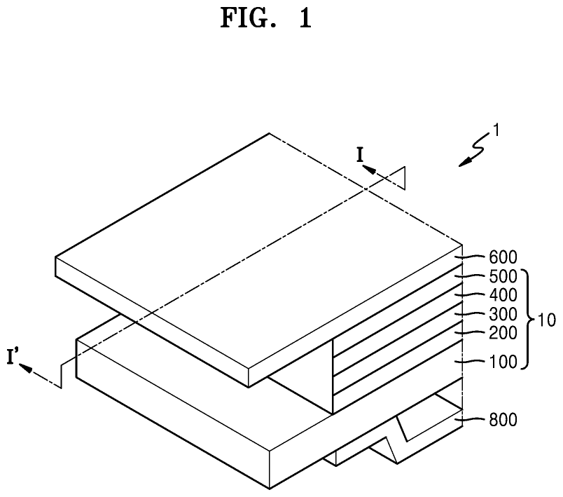

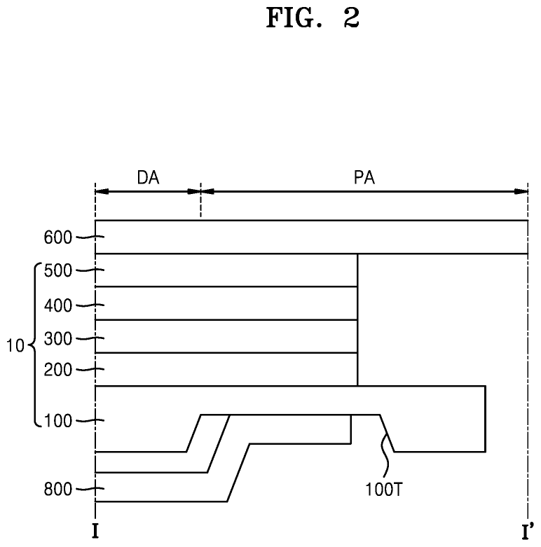

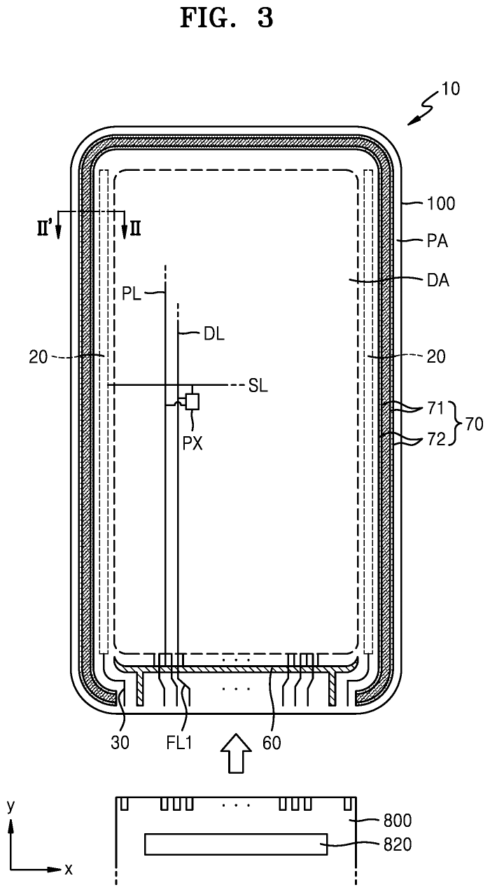

FIG. 1 is a schematic perspective view of a display apparatus 1 according to an embodiment. FIG. 2 is a schematic cross-sectional view of a cross-section of the display apparatus 1, taken along line I-I′ of FIG. 1. FIG. 3 is a schematic plan view of an area of the display apparatus 1 of FIG. 1.

According to embodiments, the display apparatus 1 may be implemented as an electronic apparatus, such as a smartphone, a mobile phone, a navigation device, a game player, a television (TV), a head unit for vehicles, a notebook computer, a laptop computer, a tablet computer, a personal media player (PMP), or a personal digital assistant (PDA). Also, the electronic apparatus may be a flexible apparatus.

Referring to FIGS. 1 to 3, according to an embodiment, the display apparatus 1 may include a substrate 100, a display layer 200, an encapsulation layer 300, a sensing layer 400, an optical layer 500, and a window 600, which are arranged over the substrate 100. In an embodiment, the substrate 100, the display layer 200, the encapsulation layer 300 the sensing layer 400 and the optical layer 500 may collectively define or constitute a display panel 10.

The display panel 10 may display an image. The display panel 10 may include a display area DA and a peripheral area PA outside the display area DA. The display area DA and the peripheral area PA may be defined in each of the substrate 100, the display layer 200, the encapsulation layer 300, the sensing layer 400, and the optical layer 500 of the display panel 10. The peripheral area PA may entirely surround the display area DA. The peripheral area PA may be a non-display area where no image is displayed. The display panel 10 may include pixels PX arranged in the display area DA.

When the display area DA is viewed in a plan view, the display area DA may have a rectangular shape in an embodiment as shown in FIG. 3. In an alternative embodiment, the display area DA may have a polygonal shape, such as a triangle, a pentagon, or a hexagon, a circular shape, an oval shape, or an amorphous shape, or the like. An edge corner of the display area DA may have a round shape.

Pixels PX connected to a scan line SL extending in an x-direction and a data line DL extending in a y-direction crossing the x-direction are arranged in the display area DA of the display layer 200, such that an image may be displayed. Each pixel PX may include a display element and a pixel circuit including a thin-film transistor configured to control light emission of the display element. The display element may include an organic light-emitting diode (OLED) or a quantum dot light-emitting diode (LED). The pixels PX may be arranged in various forms, such as a stripe arrangement, a Pentile™ arrangement (diamond arrangement), and a mosaic arrangement, in the x- and y-directions.

In an embodiment, the peripheral area PA of the display layer 200 is an area where the pixels PX are not arranged, and may be a non-display area where an image is not provided. In the peripheral area PA, various conductive lines configured to transmit an electrical signal to be applied to the display area DA, external circuits electrically connected to pixel circuits, and pads to which a printed circuit board or a driver integrated circuit (IC) chip is attached may be positioned. In an embodiment, for example, in the peripheral area PA, a scan driving circuit 20, a driving voltage supply line 60, and a common voltage supply line 70 may be arranged. In an alternative embodiment, a portion of the peripheral area PA may be implemented as the display area DA. In an embodiment, for example, a plurality of pixels PX may be arranged overlapping the scan driving circuit 20 and/or the common voltage supply line 70 at at least one corner of the display panel 10 as shown in FIG. 3. Accordingly, a dead area may be reduced, and the display area DA may be expanded.

The scan driving circuit 20 may be configured to generate a scan signal and transmit the scan signal to each pixel PX through the scan line SL. The scan signal may be a gate control signal applied to a gate of a thin-film transistor constituting the pixel circuit. In an embodiment, the scan driving circuit 20 may be provided as a pair, and the pair of scan driving circuits 20 may be disposed on opposing sides (e.g., the left and right sides) of the peripheral area PA with the display area DA therebetween. In an alternative embodiment, only a single scan driving circuit 20 may be provided on one of the opposing sides (e.g., the left or right side) of the peripheral area PA.

The substrate 100 may have a multi-layered structure including a plurality of layers. A conductive layer may be embedded in the substrate 100. The substrate 100 has one surface (front surface or upper surface) and an opposite surface (back surface or rear surface) positioned opposite to the one surface, and the display layer 200 may be disposed on the one surface of the substrate 100. A flexible printed circuit board (FPCB) 800 may be mounted on the opposite surface of the substrate 100, and a display driving circuit 820 may be disposed on the FPCB 800. The display driving circuit 820 may include, e.g., an IC chip. A chip on film (COF) or a flexible printed circuit (FPC) may be applied to the FPCB 800. At least a portion of the FPCB 800 may be mounted (or disposed) in a trench 100T formed or defined on the rear surface of the substrate 100.

A portion of the conductive layer embedded in the substrate 100 may be exposed by the trench 100T of the substrate 100, and the FPCB 800 may be electrically connected to the exposed portion of the conductive layer with a conductive adhesive or the like. The conductive layer embedded in the substrate 100 may be configured to electrically connect conductive lines in the peripheral area PA, which are arranged on the upper surface of the substrate 100, to the display driving circuit 820.

The trench 100T of the substrate 100 may correspond to a pad area of the substrate 100, which will be described below, and a portion of the conductive layer embedded in the substrate 100 may be positioned in the pad area. In an embodiment, a portion of the conductive layer positioned in the pad area may function as a pad. The FPCB 800 may be electrically connected to the pads in the pad area of the substrate 100 with a conductive adhesive or the like. The FPCB 800 may be configured to electrically connect the pads in the pad area of the substrate 100 to the display driving circuit 820. In an embodiment, the pad area may be positioned in the peripheral area PA. In an alternative embodiment, the pad area may be positioned in the display area DA.

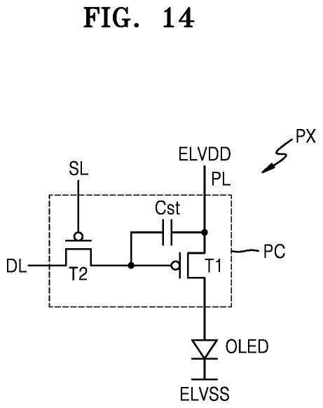

The display driving circuit 820 may be configured to generate a control signal for controlling driving of the scan driving circuit 20, and the control signal may be transmitted to the scan driving circuit 20. The display driving circuit 820 may be configured to generate a data signal, and the data signal may be transmitted to each pixel PX through fan-out line FL1 and the data line DL connected to the fan-out line FL1. The display driving circuit 820 may be configured to supply a driving voltage ELVDD (shown in FIG. 14) to the driving voltage supply line 60 and supply a common voltage ELVSS (shown in FIG. 14) to the common voltage supply line 70. The driving voltage ELVDD may be applied to the pixels PX through a driving voltage line PL connected to the driving voltage supply line 60, and the common voltage ELVSS may be applied to opposite electrodes of display elements through the common voltage supply line 70.

The driving voltage supply line 60 may extend in the x-direction in the peripheral area PA under the substrate 100. The common voltage supply line 70 has a loop shape with one side open, and may extend along the edge of the substrate 100 and partially surround the display area DA. The scan driving circuit 20 may be between the display area DA and the common voltage supply line 70. The common voltage supply line 70 may include a first (or lower) supply line 71 and a second (or upper) supply line 72. The second supply line 72 may overlap the first supply line 71 and be in contact with the first supply line 71. The second supply line 72 may be configured to electrically connect the first supply line 71 to an opposite electrode (e.g., a cathode) of an OLED of the pixel PX. In an embodiment, the common voltage supply line 70 may be electrically connected to a portion where the opposite electrode of the OLED extends to the peripheral area PA. Though FIG. 3 illustrates an embodiment where a width of the second supply line 72 is greater than a width of the first supply line 71, one or more embodiments are not limited thereto. In an alternative embodiment, the width of the second supply line 72 may be substantially equal to or greater than the width of the first supply line 71.

Portions (ends) of a signal connection line 30 connected to the scan driving circuit 20, the driving voltage supply line 60, the common voltage supply line 70, and the fan-out line FL1, which are arranged in the peripheral area PA on one side of the substrate 100, may be electrically connected to the conductive lines or the pads in the pad area embedded in the substrate 100 having a multi-layer structure.

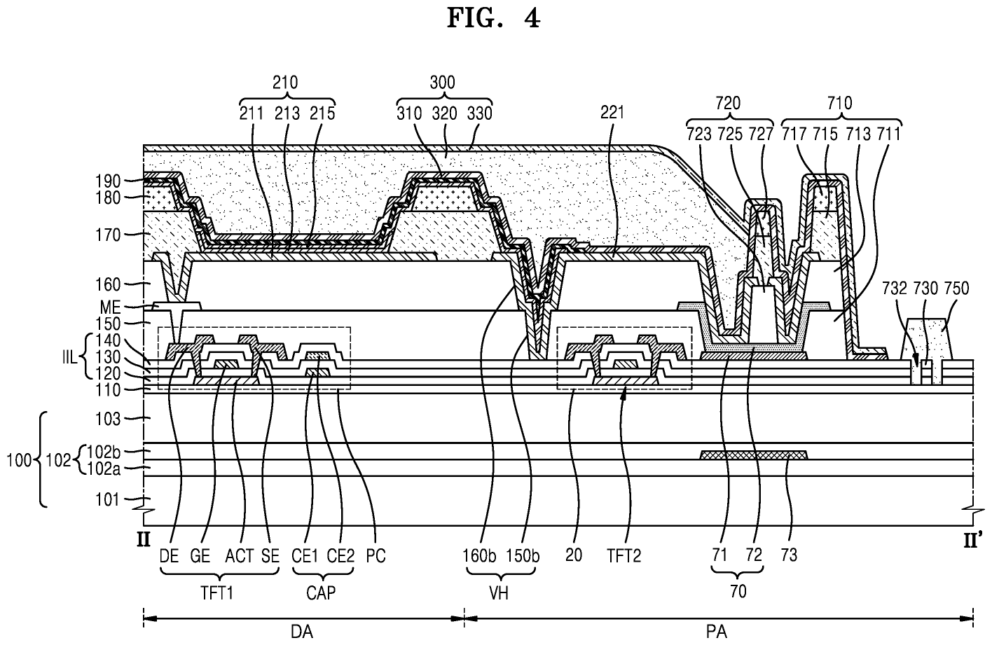

The display layer 200 may be covered with the encapsulation layer 300. As described below with reference to FIG. 4, the encapsulation layer 300 may include a thin-film encapsulation layer or a sealing substrate.

The sensing layer 400 may obtain coordinate information corresponding to an external input, e.g., a touch event. The sensing layer 400 may include a touch electrode and touch lines connected to the touch electrode. The sensing layer 400 may sense an external input by a self-capacitance method or a mutual capacitance method. The sensing layer 400 may be formed on the encapsulation layer 300. Alternatively, the sensing layer 400 may be separately formed on a touch substrate and then coupled to the encapsulation layer 300 through an adhesive layer, such as an optically clear adhesive (OCA). In an embodiment, the sensing layer 400 may be formed directly on a top surface of the encapsulation layer 300, and in such an embodiment, the adhesive layer may not be between the sensing layer 400 and the encapsulation layer 300.

The optical layer 500 may include an anti-reflective layer. The anti-reflective layer may reduce the reflectance of light (external light) incident from the outside toward the display apparatus 1. In an embodiment, the optical layer 500 may include a polarization film. In an alternative embodiment, the anti-reflective layer may include a black matrix and color filters.

The window 600 may cover the display area DA and the peripheral area PA of the display panel 10. In an embodiment, the black matrix may be disposed on the rear surface of the window 600 to correspond to the peripheral area PA where the pixels PX are not arranged. The black matrix is a colored organic layer and may be formed by, e.g., a coating method. In an embodiment, though not shown, an OCA or the like may be between the window 600 and the optical layer 500.

Though FIG. 2 illustrates an embodiment where ends of the display layer 200, the encapsulation layer 300, the sensing layer 400 and the optical layer 500 are aligned with each other, one or more embodiments are not limited thereto.

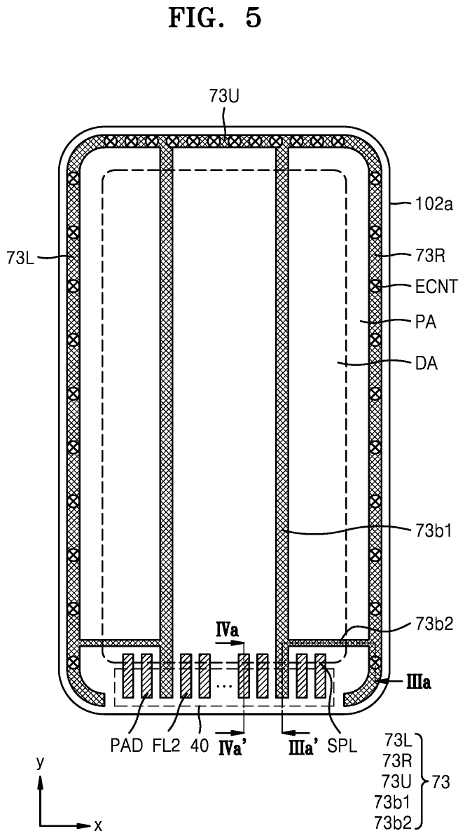

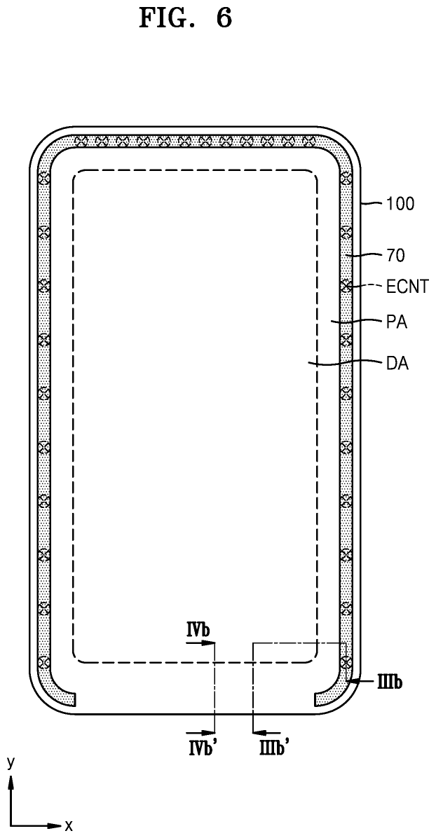

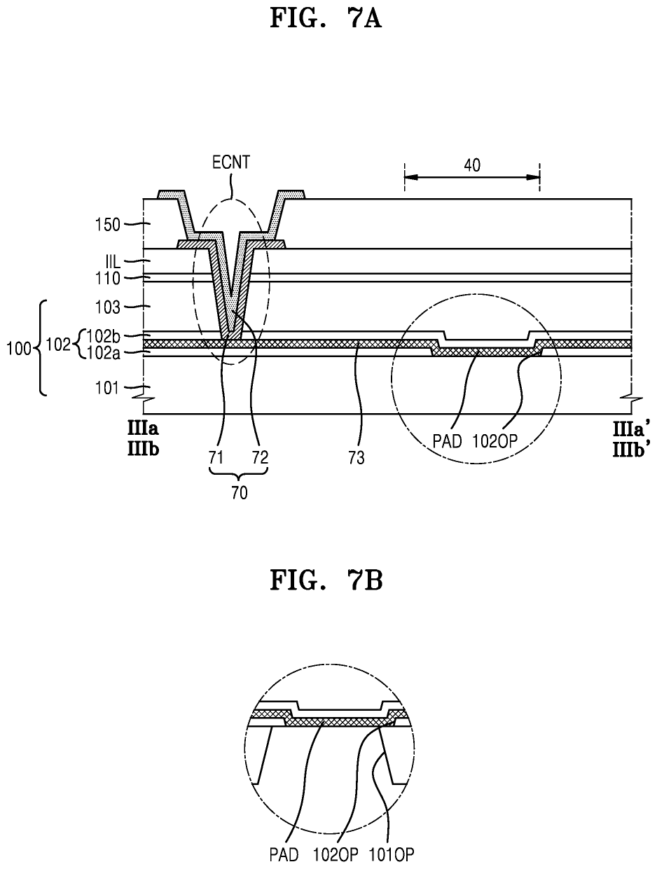

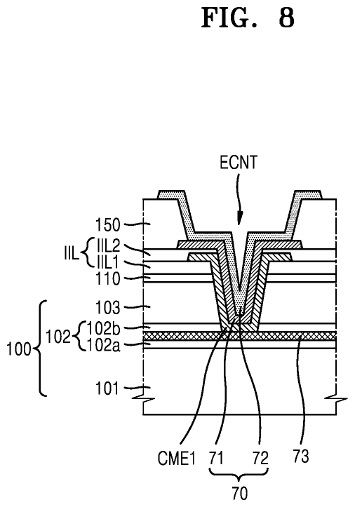

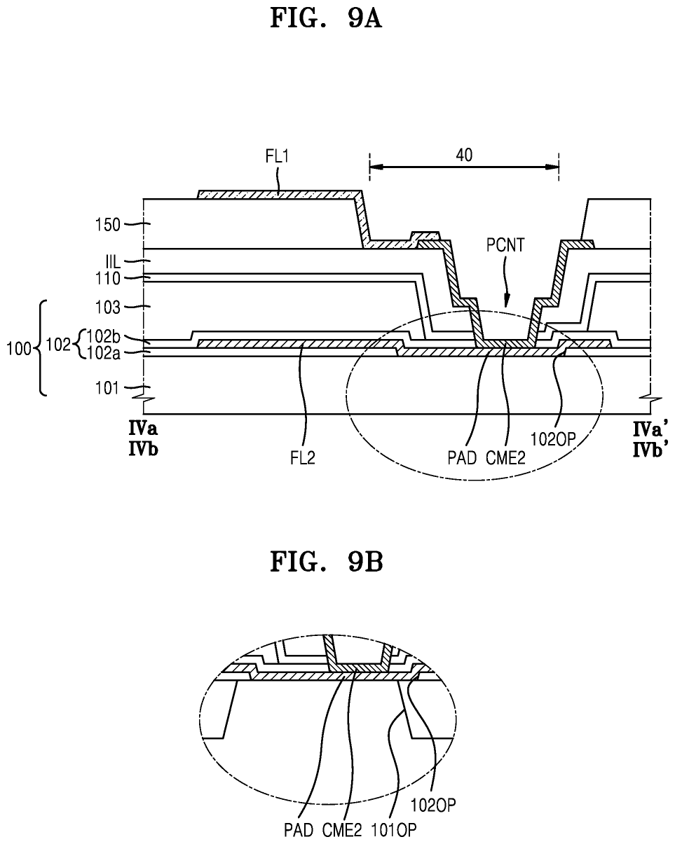

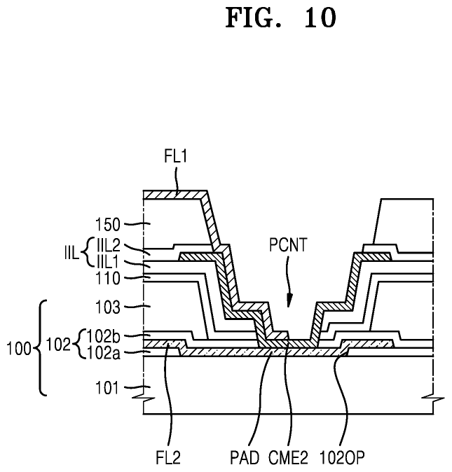

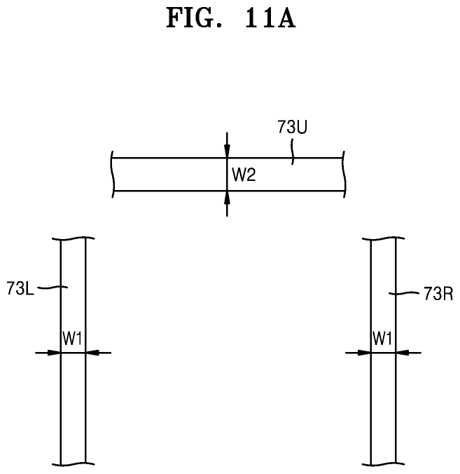

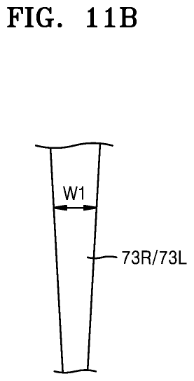

FIG. 4 is a schematic cross-sectional view of a cross-section of a display panel, taken along line II-II′ of FIG. 3. FIG. 5 is a schematic diagram showing a conductive line according to an embodiment. FIG. 6 is a schematic diagram showing a common voltage supply line 70 according to an embodiment. FIGS. 7A, 7B and 8 are schematic cross-sectional views of cross-sections of a conductive line and a common voltage supply line, taken along lines IIIa-IIIa′ and IIIb-IIIb′ of FIGS. 5 and 6, respectively. FIGS. 9A, 9B and 10 are schematic cross-sectional views of cross-sections of a conductive line and a common voltage supply line, taken along lines IVa-IVa′ and IVb-IVb′ of FIGS. 5 and 6, respectively. FIGS. 11A and 11B are diagrams of a width of a third supply line, according to an embodiment. Particularly, FIG. 7B is a cross-sectional view showing the encircled portion of FIG. 7A in which an opening 101OP is defined in the first base layer 101, and FIG. 9B is a cross-sectional view showing the encircled portion of FIG. 9A in which an opening 101OP is defined in the first base layer 101.

Referring to FIG. 4, the substrate 100 may include a glass material or a polymer resin. The substrate 100 may include a multi-layer, that is, have a multi-layer structure. In an embodiment, for example, the substrate 100 may include a first base layer 101, a barrier layer 102, and a second base layer 103.

Each of the first base layer 101 and the second base layer 103 may include a polymer resin. In an embodiment, for example, the first base layer 101 and the second base layer 103 may include a polymer resin, such as polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose triacetate (TAC), cellulose acetate propionate (CAP), or the like. Each of the first base layer 101 and the second base layer 103 may include a transparent polymer resin.

The barrier layer 102 is a layer that prevents the penetration of foreign substances, and may have a single layer structure or a multi-layer structure, each layer therein including an inorganic material, such as silicon nitride or silicon oxide. The barrier layer 102 may include a first barrier layer 102a and a second barrier layer 102b on the first barrier layer 102a.

A conductive layer may be embedded between the first base layer 101 and the second base layer 103. The conductive layer may be between the first barrier layer 102a and the second barrier layer 102b. The conductive layer may include a plurality of conductive lines. In an embodiment, as shown in FIG. 5, the plurality of conductive lines may be arranged over the first barrier layer 102a of the substrate 100. The plurality of conductive lines may include a third supply line 73 and auxiliary lines SPL.

The third supply line 73 may extend along the edge of the substrate 100. The third supply line 73 may have a loop shape with one side open and partially surround the display area DA. The third supply line 73 may include a main line including a left portion 73L, a right portion 73R, and an upper portion 73U, which are respectively disposed on the left, right, and upper sides of the peripheral area PA. The left portion 73L and the right portion 73R of the third supply line 73 may extend in the y-direction, and the upper portion 73U may extend in the x-direction. The third supply line 73 may further include at least one vertical line 73b1 extending in the y-direction and at least one horizontal line 73b2 extending in the x-direction, which cross the display area DA. The at least one horizontal line 73b2 may be positioned around a pad area 40. The third supply line 73 may be configured to electrically connect the display driving circuit 820 to the common voltage supply line 70. The third supply line 73 may be configured to receive the common voltage ELVSS from the display driving circuit 820 and transmit the common voltage ELVSS to the common voltage supply line 70.

The vertical line 73b1 and the horizontal line 73b2 may be provided as a plurality of vertical lines 73b1 and a plurality of horizontal lines 73b2. The horizontal line 73b2 may be arranged adjacent to the pad area 40. The third supply line 73 may have a lattice structure by the horizontal line 73b2 and the vertical line 73b1, such that a voltage drop of the common voltage ELVSS may be reduced. A width of the horizontal line 73b2 adjacent to the pad area 40 may be less than a width of the vertical line 73b1. In an embodiment, as shown in FIG. 5, the horizontal line 73b2 extends in the x-direction between the left portion 73L of the main line and the vertical line 73b1 and between the right portion 73R and the vertical line 73b1, but the horizontal line 73b2 may extend in the x-direction between a pair of vertical lines 73b1.

The auxiliary lines SPL may be configured to electrically connect the display driving circuit 820 to the signal connection line 30, the driving voltage supply line 60, and fan-out lines FL1. For convenience of description, among the auxiliary lines SPL, conductive lines connected to the fan-out lines FL1 may be referred to as lower fan-out lines FL2.

The pad area 40 may be defined in the first barrier layer 102a of the substrate 100. A plurality of pads PAD may be arranged in the pad area 40. The plurality of pads PAD and the plurality of conductive lines on the first barrier layer 102a may include a same material as each other. The plurality of pads PAD may be defined by a portion of the third supply line 73 and the auxiliary lines SPL. In an embodiment, for example, ends (or end portions) of the vertical lines 73b1 of the third supply line 73, which are positioned in the pad area 40, and ends (or end portions) of the lower fan-out lines FL2 may function as the pads PAD.

As shown in FIGS. 7B and 9B, an opening 102OP corresponding to the pad area 40 may be defined in the first barrier layer 102a, and the third supply line 73 and the auxiliary lines SPL may be disposed over the first barrier layer 102a. In the pad area 40, the third supply line 73 and the auxiliary lines SPL may be disposed in the opening 102OP of the first barrier layer 102a and be in contact with the first base layer 101. The third supply line 73 is shown in FIG. 7A, and a lower fan-out line FL2 is shown in FIG. 9A. The second barrier layer 102b and the second base layer 103 may be arranged over the third supply line 73 and the auxiliary lines SPL.

A buffer layer 110 may be disposed over the substrate 100 to prevent impurities from penetrating into a semiconductor layer of a thin-film transistor. The buffer layer 110 may include an inorganic insulator, such as silicon nitride or silicon oxide, and may have a single layer structure or a multi-layer structure. In an embodiment, a barrier layer may be further provided between the substrate 100 and the buffer layer 110.

The pixel circuit PC and an OLED 210 electrically connected to the pixel circuit PC may be arranged in the display area DA of the substrate 100. The pixel circuit PC may include a first thin-film transistor TFT1 and a capacitor CAP. When the OLED 210 is electrically connected to the pixel circuit PC, it may be understood that a pixel electrode 211 is electrically connected to the pixel circuit PC. The first thin-film transistor TFT1 may include a semiconductor layer ACT, a gate electrode GE, a source electrode SE, and a drain electrode DE. The semiconductor layer ACT may include amorphous silicon, polycrystalline silicon, or an organic semiconductor material. The gate electrode GE may be arranged over the semiconductor layer ACT. The capacitor CAP may include a lower electrode CE1 and an upper electrode CE2.

A first gate insulating layer 120 may between the semiconductor layer ACT and the gate electrode GE. A second gate insulating layer 130 and an interlayer insulating layer 140 may be between the gate electrode GE and, the source electrode SE and the drain electrode DE. The second gate insulating layer 130 may be between the lower electrode CE1 and the upper electrode CE2 of the capacitor CAP. Each of the first gate insulating layer 120, the second gate insulating layer 130, and the interlayer insulating layer 140 may include an inorganic material, such as silicon oxide, silicon nitride, or silicon oxynitride, and may have a single-layered or multi-layered structure. The first gate insulating layer 120, the second gate insulating layer 130, and the interlayer insulating layer 140 may collectively define or be collectively referred to as an inorganic insulating layer IIL.

The source electrode SE and the drain electrode DE may be arranged over the interlayer insulating layer 140. Each of the source electrode SE and the drain electrode DE may be electrically connected to the semiconductor layer ACT through a contact hole defined or formed in the first gate insulating layer 120, the second gate insulating layer 130, and the interlayer insulating layer 140.

A first planarization layer 150 and a second planarization layer 160 may be sequentially arranged over the interlayer insulating layer 140. Each of the first planarization layer 150 and the second planarization layer 160 may include an organic insulating material, such as a general-purpose polymer such as polymethyl methacrylate (PMMA) or polystyrene (PS), polymer derivatives having a phenol-based group, an acrylic-based polymer, an imide-based polymer, an aryl ether-based polymer, an amide-based polymer, a fluorine-based polymer, a p-xylene-based polymer, a vinyl alcohol-based polymer, or any blend thereof. A connection electrode ME may be disposed between the first planarization layer 150 and the second planarization layer 160. A data line, a driving voltage line, etc. may be further disposed or provided between the first planarization layer 150 and the second planarization layer 160.

In the display area DA, the OLED 210, which is a display element, may be arranged over the second planarization layer 160. The OLED 210 may include the pixel electrode 211, an opposite electrode 215, and an intermediate layer 213 provided therebetween and including an emission layer.

The pixel electrode 211 may be disposed on the second planarization layer 160, and the pixel electrode 211 may be in contact with the source electrode SE or the drain electrode DE of the first thin-film transistor TFT1 and be electrically connected to the first thin-film transistor TFT1. The pixel electrode 211 may be electrically connected to the first thin-film transistor TFT1 through the connection electrode ME.

A pixel-defining layer 170 may be disposed on the second planarization layer 160. The pixel-defining layer 170 covers the edge of a pixel electrode 211 of each pixel PX, has an opening that exposes a portion of the pixel electrode 211, and thus may define the pixel PX. The pixel-defining layer 170 may include an organic material, such as PI or HMDSO. In an embodiment, a spacer 180 may further be disposed on the pixel-defining layer 170. The spacer 180 may include an organic material or an inorganic material.

The intermediate layer 213 of the OLED 210 may include an emission layer. The emission layer may include a polymer organic material or a low molecular weight organic material that emits light having a certain color. In an embodiment, the intermediate layer 213 may include a first functional layer arranged under the emission layer and/or a second functional layer arranged over the emission layer. The first functional layer and/or the second functional layer may include an integral layer over the plurality of pixel electrodes 211 or may include a patterned layer to correspond to each of the plurality of pixel electrodes 211.

The first functional layer may include a single layer or a multi-layer. In an embodiment, for example, the first functional layer may include a hole transport layer (HTL) having a single-layered structure. The first functional layer may include a hole injection layer (HIL) and an HTL. The second functional layer may have a single layer structure or a multi-layer structure. The second functional layer may include an electron transport layer (ETL) and/or an electron injection layer (EIL). Alternatively, the second functional layer may be omitted.

The opposite electrode 215 may be disposed on the front surface of the display area DA. The opposite electrode 215 may be integrally formed as a single unitary and indivisible body over the plurality of OLEDs 210 and may face the plurality of pixel electrodes 211. The opposite electrode 215 may extend from the display area DA to the peripheral area PA and be arranged over the display area DA and the peripheral area PA.

In an embodiment, as shown in FIG. 6, the common voltage supply line 70 is positioned in the peripheral area PA and may be configured to transmit the common voltage ELVSS to the opposite electrode 215. The common voltage supply line 70 may include the first supply line 71 disposed on the interlayer insulating layer 140 and the second supply line 72 disposed on the first planarization layer 150. In an embodiment where various conductive layers are formed in the display area DA, the common voltage supply line 70 may be simultaneously formed using a same material as the various conductive layers. In an embodiment, for example, when the source electrode SE and the drain electrode DE of the first thin-film transistor TFT1 are formed on the interlayer insulating layer 140 in the display area DA, the first supply line 71 may be simultaneously formed on the interlayer insulating layer 140 in the peripheral area PA by using a same material as the source electrode SE and the drain electrode DE. Accordingly, the first supply line 71, the source electrode SE, and the drain electrode DE may have a same structure as each other. In an embodiment, when the connection electrode ME, a data line, and a driving voltage line are formed on the first planarization layer 150 in the display area DA, the second supply line 72 may be simultaneously formed on the first planarization layer 150 in the peripheral area PA by using a same material as the connection electrode ME, the data line, and the driving voltage line. Accordingly, the second supply line 72 and the connection electrode ME may have a same structure as each other.

The common voltage supply line 70 may overlap the third supply line 73. The common voltage supply line 70 may be electrically connected to the third supply line 73 in an electrical connection area, e.g., a contact area ECNT. In an embodiment, as shown in FIG. 7A, the first supply line 71 on the inorganic insulating layer IIL may be in direct contact with the third supply line 73 through contact holes of the second barrier layer 102b, the second base layer 103, the buffer layer 110, and the inorganic insulating layer IIL in the contact area ECNT. In an alternative embodiment, as shown in FIG. 8, an intermediate electrode CME1 may be between a lower inorganic insulating layer IIL1 and an upper inorganic insulating layer IIL2 in the contact area ECNT, and the common voltage supply line 70 and the third supply line 73 may be electrically connected to each other by the intermediate electrode CME1. The intermediate electrode CME1 may be in direct contact with the third supply line 73 through contact holes of the second barrier layer 102b, the second base layer 103, the buffer layer 110, and the lower inorganic insulating layer IIL1. The first supply line 71 on the inorganic insulating layer IIL may be in direct contact with the intermediate electrode CME1 through a contact hole of the upper inorganic insulating layer IIL2 in the contact area ECNT.

In an embodiment, the lower inorganic insulating layer IIL1 may include the first gate insulating layer 120, the upper inorganic insulating layer IIL2 may include the second gate insulating layer 130 and the interlayer insulating layer 140, and the intermediate electrode CME1, the gate electrode GE of the first thin-film transistor TFT1, and the lower electrode CE1 of the capacitor CAP may include a same material as each other. In an alternative embodiment, the lower inorganic insulating layer IIL1 may include the first gate insulating layer 120 and the second gate insulating layer 130, the upper inorganic insulating layer IIL2 may include the interlayer insulating layer 140, and the intermediate electrode CME1 and the upper electrode CE2 of the capacitor CAP may include a same material as each other.

In an embodiment, as shown in FIG. 3, the signal connection line 30, the driving voltage supply line 60, and the fan-out lines FL1 may be arranged in the peripheral area PA. In an embodiment, at least one selected from the signal connection line 30, the driving voltage supply line 60 and the fan-out lines FL1 may be disposed in (or directly on) a same layer as the gate electrode GE of the first thin-film transistor TFT1 and the lower electrode CE1 of the capacitor CAP and include a same material as the gate electrode GE of the first thin-film transistor TFT1 and the lower electrode CE1 of the capacitor CAP. Alternatively, at least one selected from the signal connection line 30, the driving voltage supply line 60 and the fan-out lines FL1 may be disposed in (or directly on) a same layer as the upper electrode CE2 of the capacitor CAP and include a same material as the upper electrode CE2 of the capacitor CAP. Alternatively, at least one selected from the signal connection line 30, the driving voltage supply line 60 and the fan-out lines FL1 may be disposed in (or directly on) a same layer as the source electrode SE an the drain electrode DE of the first thin-film transistor TFT1 and include a same material as the source electrode SE an the drain electrode DE of the first thin-film transistor TFT1. Alternatively, at least one selected from the signal connection line 30, the driving voltage supply line 60 and the fan-out lines FL1 may be disposed on the first planarization layer 150 or the second planarization layer 160.

FIG. 9A illustrate an embodiment in which the fan-out line FL1 is disposed on the first planarization layer 150 and is in contact with an intermediate electrode CME2 disposed on the inorganic insulating layer IIL. In the pad area 40, the lower fan-out line FL2 (i.e., a portion thereof functioning as the pad PAD) may be exposed by openings of the second barrier layer 102b, the second base layer 103, the buffer layer 110, and the inorganic insulating layer IIL. The intermediate electrode CME2 may be arranged in the openings of the second barrier layer 102b, the second base layer 103, the buffer layer 110, and the inorganic insulating layer IIL, and may be in contact with the lower fan-out line FL2 exposed in a contact area PCNT corresponding to the pad area 40. In an alternative embodiment, as shown in FIG. 10, the intermediate electrode CME2 may be between the lower inorganic insulating layer 111_1 and the upper inorganic insulating layer IIL2 in the contact area PCNT, and the fan-out line FL1 and the lower fan-out line FL2 may be electrically connected to each other by the intermediate electrode CME2. The intermediate electrode CME2 may be in contact with the lower fan-out line FL2 exposed by the openings of the second barrier layer 102b, the second base layer 103, the buffer layer 110, and the lower inorganic insulating layer IIL1. The fan-out line FL1 may be arranged in openings of the upper inorganic insulating layer IIL2 and the first planarization layer 150 and the openings of the second barrier layer 102b, the second base layer 103, the buffer layer 110, and the lower inorganic insulating layer IIL1, and may be in contact with the intermediate electrode CME2.

In an embodiment, the lower inorganic insulating layer IIL1 may include the first gate insulating layer 120, the upper inorganic insulating layer IIL2 may include the second gate insulating layer 130 and the interlayer insulating layer 140, and the intermediate electrode CME2, the gate electrode GE of the first thin-film transistor TFT1, and the lower electrode CE1 of the capacitor CAP may include a same material as each other. In an alternative embodiment, the lower inorganic insulating layer IIL1 may include the first gate insulating layer 120 and the second gate insulating layer 130, the upper inorganic insulating layer IIL2 may include the interlayer insulating layer 140, and the intermediate electrode CME2 and the upper electrode CE2 of the capacitor CAP may include a same material as each other.

Though FIGS. 9A, 9B and 10 illustrate an embodiment where the fan-out line FL1 is electrically connected to the lower fan-out line FL2 through the intermediate electrode CME2, one or more embodiments are not limited thereto. In an alternative embodiment, for example, by being disposed in the contact area PCNT on a layer on which the low fan-out line FL2 is disposed, the fan-out line FL1 may be in direct contact with and be electrically connected to the lower fan-out line FL2 in the contact area PCNT without the intermediate electrode CME2.

Though not shown in FIGS. 7A to 10, at least one insulating layer including a same material as the second planarization layer 160, the pixel-defining layer 170, and the spacer 180 may be arranged over the common voltage supply line 70, the signal connection line 30, the driving voltage supply line 60, and the fan-out line FL1. The at least one insulating layer including a same material as the second planarization layer 160, the pixel-defining layer 170, and the spacer 180 may cover at least a portion of the common voltage supply line 70, the signal connection line 30, the driving voltage supply line 60, and the fan-out line FL1. The at least one insulating layer including the same material as at least one selected from the second planarization layer 160, the pixel-defining layer 170 and the spacer 180 may cover the contact areas ECNT and PCNT.

A portion of the opposite electrode 215 extending to the peripheral area PA may be electrically connected to the common voltage supply line 70 in the peripheral area PA. The opposite electrode 215 may be electrically connected to the common voltage supply line 70 through a connection electrode layer 221, which is a conductive layer, without directly contacting the common voltage supply line 70. The connection electrode layer 221 may be disposed in (or directly on) a same layer as the pixel electrode 211, e.g., directly on the second planarization layer 160, spaced apart from the pixel electrode 211, and insulated from the pixel electrode 211. The connection electrode layer 221 may extend onto the common voltage supply line 70 exposed by an opening formed in the second planarization layer 160 and be electrically connected to the common voltage supply line 70. In the peripheral area PA, the opposite electrode 215 may be in contact with the connection electrode layer 221, and the connection electrode layer 221 may be in contact with the common voltage supply line 70. When the pixel electrode 211 in the display area DA is formed on the second planarization layer 160, the connection electrode layer 221 may be simultaneously formed on the second planarization layer 160 in the peripheral area PA by using a same material as the pixel electrode 211. Accordingly, the connection electrode layer 221 and the pixel electrode 211 may have the same structure. The connection electrode layer 221 may cover an exposed portion of the common voltage supply line 70. Therefore, the common voltage supply line 70 may be effectively prevented from being damaged in a process of forming a first dam 710 or a second dam 720.

In an embodiment, the first planarization layer 150 and the second planarization layer 160 may form a valley VH in the peripheral area PA to prevent impurities, such as oxygen or moisture, from the outside from penetrating into the display area DA through the first planarization layer 150 and the second planarization layer 160. The valley VH may be formed or defined by an opening 150b of the first planarization layer 150 and an opening 160b of the second planarization layer 160, which overlap each other. The connection electrode layer 221 and the opposite electrode 215 may entirely cover the opening 150b and the opening 160b.

The scan driving circuit 20 may be arranged in the peripheral area PA of the substrate 100. The scan driving circuit 20 may include a second thin-film transistor TFT2. The second thin-film transistor TFT2 may be formed through a same process as the first thin-film transistor TFT1, and thus, any repetitive detailed description of the second thin-film transistor TFT2 is not provided herein. The scan driving circuit 20 may be between the valley VH and the common voltage supply line 70.

A capping layer 190 may be disposed on the opposite electrode 215. The capping layer 190 may cover the opposite electrode 215, extend to outside the opposite electrode 215, and be in contact with the connection electrode layer 221 positioned under the opposite electrode 215. The capping layer 190 may be disposed over the display area DA and extend to the peripheral area PA outside the display area DA.

The encapsulation layer 300 may be arranged over the capping layer 190. The encapsulation layer 300 may protect the OLED 210 from moisture or oxygen from the outside. The encapsulation layer 300 may extend form the display area DA to the peripheral area PA. In an embodiment, the encapsulation layer 300 may have a multi-layered structure. The encapsulation layer 300 may include a first inorganic layer 310, an organic layer 320, and a second inorganic layer 330.

The first inorganic layer 310 covers the capping layer 190 and may include silicon oxide, silicon nitride, silicon oxynitride, or the like. The first inorganic layer 310 is formed along a structure thereunder and thus may not have a flat upper surface.

The organic layer 320 may cover the first inorganic layer 310 and have a sufficient thickness. The upper surface of the organic layer 320 may be substantially flat over the display area DA. The organic layer 320 may include at least one selected from PET, PEN, PC, PI, polyethylene sulfonate, polyoxymethylene, PAR, and hexamethyldisiloxane.

The second inorganic layer 330 covers the organic layer 320 and may include silicon oxide, silicon nitride, silicon oxynitride, or the like. The second inorganic layer 330 extends to the outside of the organic layer 320 and is in contact with the first inorganic layer 310, such that the organic layer 320 may not be exposed to the outside.

When the organic layer 320 of the encapsulation layer 300 is formed, it is desired to limit the material for forming the organic layer 320 to be positioned within a preset area. Accordingly, in an embodiment, the first dam 710 may be formed in the peripheral area PA. The first dam 710 may have a multi-layered structure. The first dam 710 may include a first layer 711, a second layer 713, a third layer 715, and a fourth layer 717, which are disposed sequentially in a direction away from the substrate 100. The first layer 711 and the first planarization layer 150 may be simultaneously formed using a same material as each other. The second layer 713 and the second planarization layer 160 may be simultaneously formed using a same material as each other. The third layer 715 and the pixel-defining layer 170 may be simultaneously formed using a same material as each other. The fourth layer 717 and the spacer 180 may be simultaneously formed using a same material as each other.

The second dam 720 may be between the first dam 710 and the valley VH. The second dam 720 may be positioned over a portion of the common voltage supply line 70. The second dam 720 may include a multi-layered structure and include fewer layers than the first dam 710, such that a height of the second dam 720 from the substrate 100 is lower than that of the first dam 710. The second dam 720 may include a first layer 723, a second layer 725, and a third layer 727. The first layer 723 and the second planarization layer 160 may be simultaneously formed using a same material as each other. The second layer 725 and the pixel-defining layer 170 may be simultaneously formed using a same material as each other. The third layer 727 and the spacer 180 may be simultaneously formed using a same material as each other.

The first inorganic layer 310 may cover the second dam 720 and the first dam 710 and extend to the outside of the first dam 710. The position of the organic layer 320 on the first inorganic layer 310 is limited by the second dam 720, such that the material for forming the organic layer 320 may be effectively prevented from overflowing to the outside of the second dam 720. Even when the material for forming the organic layer 320 partially overflows to the outside of the second dam 720, the position of the organic layer 320 is limited by the first dam 710, and thus, the material for forming the organic layer 320 may be effectively prevented from moving toward the edge of the substrate 100.

In an embodiment, an anti-crack dam 730 may be positioned in the peripheral area PA. The anti-crack dam 730 may extend along at least a portion of the edge of the substrate 100. In an embodiment, for example, the anti-crack dam 730 may have a shape that surrounds the display area DA. In some sections, the anti-crack dam 730 may also have a discontinuous shape. The anti-crack dam 730 may include a layer including a same material as the first gate insulating layer 120, a layer including a same material as the second gate insulating layer 130, and a layer including a same material as the interlayer insulating layer 140. The anti-crack dam 730 may be disposed on the buffer layer 110. Alternatively or selectively, the anti-crack dam 730 is disposed on a layer positioned under the buffer layer 110 and may also include a layer including a same material as the buffer layer 110. Single anti-crack dam 730 may be provided or a plurality of anti-crack dams 730 may be provided spaced apart from each other. A transfer prevention groove 732 formed by removing the first gate insulating layer 120, the second gate insulating layer 130, and the interlayer insulating layer 140 may be formed on at least one side of the anti-crack dam 730. In addition, the anti-crack dam 730 may be covered by a cover layer 750. The cover layer 750 may include an organic material. That is, the cover layer 750 may be a layer including an organic material that covers the anti-crack dam 730 including an inorganic material. The cover layer 750 may fill the transfer prevention groove 732 and cover the anti-crack dam 730.

In an embodiment, as shown in FIGS. 7A, 7B, 9A and 9B, a portion of the first base layer 101 corresponding to the pad area 40 is removed from the rear surface of the substrate 100, and accordingly, an opening 101OP of the first base layer 101 may be defined. The first base layer 101 may be removed by using laser, plasma, or the like. In an embodiment, the opening 101OP of the first base layer 101 may define the trench 100T defined on the rear surface of the substrate 100 as shown in FIG. 2. At least a portion of the FPCB 800 may be mounted in the opening 101OP of the first base layer 101 by a conductive adhesive or the like and may be electrically connected to the pads PAD of the pad area 40. The third supply line 73 and the auxiliary lines SPL may be configured to receive an electrical signal (e.g., a common voltage, a control signal, a driving voltage, a data signal, or the like) from the display driving circuit 820 of the FPCB 800 connected to the pads PAD, and transmit the electrical signal to the common voltage supply line 70, the signal connection line 30, the driving voltage supply line 60, and the fan-out lines FL1.

A width of the third supply line 73 and the number of contact areas ECNT in which the third supply line 73 is in contact with the common voltage supply line 70 may be adjusted or determined in consideration of a voltage drop of the common voltage ELVSS.

In an embodiment, widths of the left portion 73L, the right portion 73R, and the upper portion 73U constituting the main line of the third supply line 73 may be the same as each other. In an alternative embodiment, because the voltage drop of the common voltage ELVSS increases in a direction away from the pad area 40, the width of the third supply line 73 may be adjusted based on a relative position of the third supply line 73 from the pad area 40. In an embodiment, as shown in FIG. 11A, in the main line of the third supply line 73, a width W2 of the upper portion 73U positioned relatively far from the pad area 40 may be greater than a width W1 of each of the left portion 73L and the right portion 73R. In an alternative embodiment, as shown in FIG. 11B, a width W1 of each of the left portion 73L and the right portion 73R may gradually increase in a direction away from the pad area 40.

In an embodiment, in the left portion 73L, the right portion 73R, and the upper portion 73U constituting the main line of the third supply line 73, the number of contact area ECNT per unit length may be the same as each other. In an alternative embodiment, because the voltage drop of the common voltage ELVSS increases in a direction away from the pad area 40, the number of contact areas ECNT per unit length of the third supply line 73 may be adjusted according to the relative position (of the third supply line 73 from the pad area 40. In an embodiment, as shown in FIG. 5, in the main line of the third supply line 73, the number of contact areas ECNT per unit length of the upper portion 73U positioned relatively far from the pad area 40 may be greater than the number of contact areas ECNT per unit length of the left portion 73L and the right portion 73R. An interval between the contact areas ECNT in the upper portion 73U may be less than an interval between the contact areas ECNT in the left portion 73L and the right portion 73R. The interval between the contact areas ECNT in the left portion 73L and the right portion 73R may decrease in a direction away from the pad area 40.

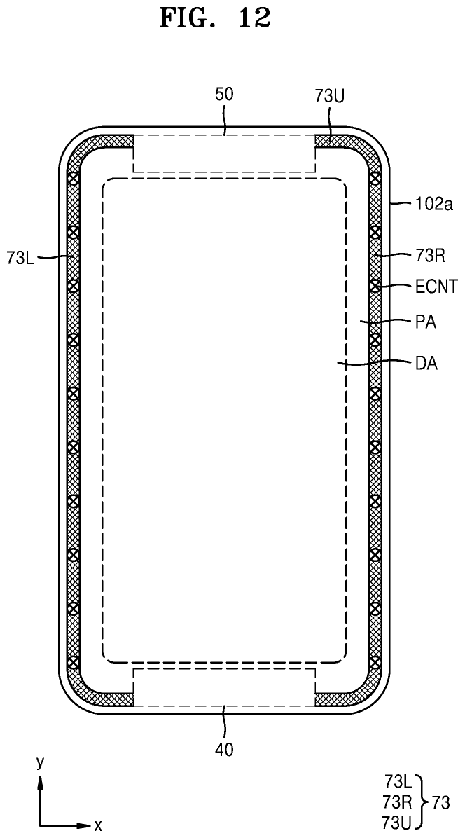

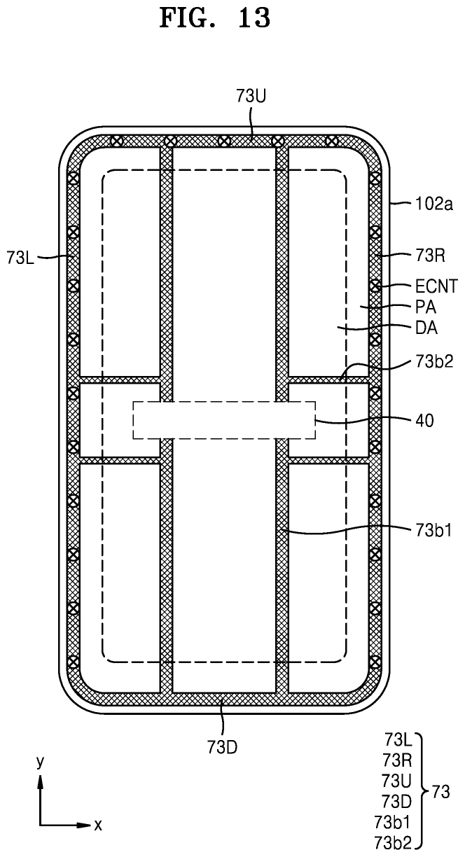

FIGS. 12 and 13 are diagrams showing a third supply line 73 and a pad area 40, according to alternative embodiments.

FIG. 5 illustrates an embodiment in which one pad area 40 is arranged in the peripheral area PA of the first barrier layer 102a, and one side of the third supply line 73 is open, but one or more embodiments are not limited thereto. In an embodiment, for example, a position of the pad area 40 and/or number of pad areas 40, and/or an arrangement shape of the third supply line 73 may be variously modified based on characteristics of the display panel.

In an embodiment, as shown in FIG. 12, two or more pad areas 40 and 50 may be defined in the peripheral area PA of the first barrier layer 102a of the substrate 100. The pad area 40 may be an area to which the FPCB 800, in which the display driving circuit 820 is arranged, is connected. The pad area 50 may be an area to which an additional FPCB in which a voltage generation circuit configured to supply the common voltage ELVSS to the third supply line 73 is arranged is connected. As shown in FIG. 7B, an end of the third supply line 73 may be exposed in the pad area 50 by the opening 102OP of the first barrier layer 102a and the opening 101OP of the first base layer 101, and may be connected to the additional FPCB on the rear surface of the substrate 100.

In an embodiment shown in FIG. 12, because the pad area 50 is additionally positioned in the upper portion 73U of the third supply line 73, the third supply line 73 may be configured to receive the common voltage ELVSS from each of the display driving circuit 820 and an additional voltage generation circuit, and accordingly, in such an embodiment the vertical line 73b1 and the horizontal line 73b2 shown in FIG. 5 may be omitted. The number per unit length of the contact areas ECNT in which the left portion 73L of the third supply line 73 is electrically connected to the common voltage supply line 70 may be equal to the number per unit length of the contact areas ECNT in which the right portion 73R is electrically connected to the common voltage supply line 70.

In an alternative embodiment, as shown in FIG. 13, the pad area 40 may be defined in the display area DA of the first barrier layer 102a of the substrate 100. The third supply line 73 may include a main line including the left portion 73L, the right portion 73R, the upper portion 73U, and a lower portion 73D, which are respectively arranged on the left, right, upper, and lower sides of the peripheral area PA. The third supply line 73 may further include at least one vertical line 73b1 extending in the y-direction and at least one horizontal line 73b2 extending in the x-direction, which cross the display area DA. The at least one horizontal line 73b2 may be positioned around the pad area 40. The width of the horizontal line 73b2 adjacent to the pad area 40 may be less than the width of the vertical line 73b1. The number per unit length of the contact areas ECNT in which the left portion 73L of the third supply line 73 is electrically connected to the common voltage supply line 70, the number per unit length of the contact areas ECNT in which the right portion 73R is electrically connected to the common voltage supply line 70, and the number per unit length of the contact areas ECNT in which the upper portion 73U is electrically connected to the common voltage supply line 70 may be the same as each other. In such an embodiment, as shown in FIG. 6, because the common voltage supply line 70 has a structure in which a portion of the common voltage supply line 70 corresponding to the lower side of the substrate 100 is open, the lower portion 73D of the third supply line 73 may not be in contact with the common voltage supply line 70. In an embodiment of FIG. 13, the auxiliary lines SPL (e.g., FIG. 5) may have a length extending from the lower portion 73D of the third supply line 73 to the pad area 40.

FIGS. 14 to 16 are equivalent circuit diagrams of a pixel PX according to an embodiment.

In an embodiment, as shown in FIG. 14, the pixel PX may include the pixel circuit PC and the organic light-emitting diode OLED, which is a display element connected to the pixel circuit PC. The pixel circuit PC may include a first transistor T1, a second transistor T2, and a capacitor Cst. The pixel PX may emit, e.g., red, green, blue, or white light from the organic light-emitting diode OLED. The first transistor T1 and the second transistor T2 may be implemented as thin-film transistors.

The second transistor T2, which is a switching transistor, may be connected to the scan line SL and the data line DL and may be configured to transmit, to the first transistor T1, a data signal input from the data line DL in response to a scan signal input from the scan line SL. The capacitor Cst may be connected to the second transistor T2 and the driving voltage line PL and may be configured to store a voltage corresponding to a difference between a voltage received from the second transistor T2 and a first power voltage ELVDD supplied to the driving voltage line PL.

The first transistor T1, which is a driving transistor, may be connected to the driving voltage line PL and the capacitor Cst and may be configured to control a driving current flowing through the organic light-emitting diode OLED from the driving voltage line PL in response to a value of the voltage stored in the capacitor Cst. The organic light-emitting diode OLED may emit light having a certain luminance corresponding to the driving current. An opposite electrode (e.g., a cathode) of the organic light-emitting diode OLED may be configured to receive the common voltage ELVSS.

Though FIG. 14 illustrates an embodiment where the pixel circuit PC includes two transistors and one capacitor, one or more embodiments are not limited thereto. The number of transistors and the number of capacitors may be variously changed based on the design of the pixel circuit PC.

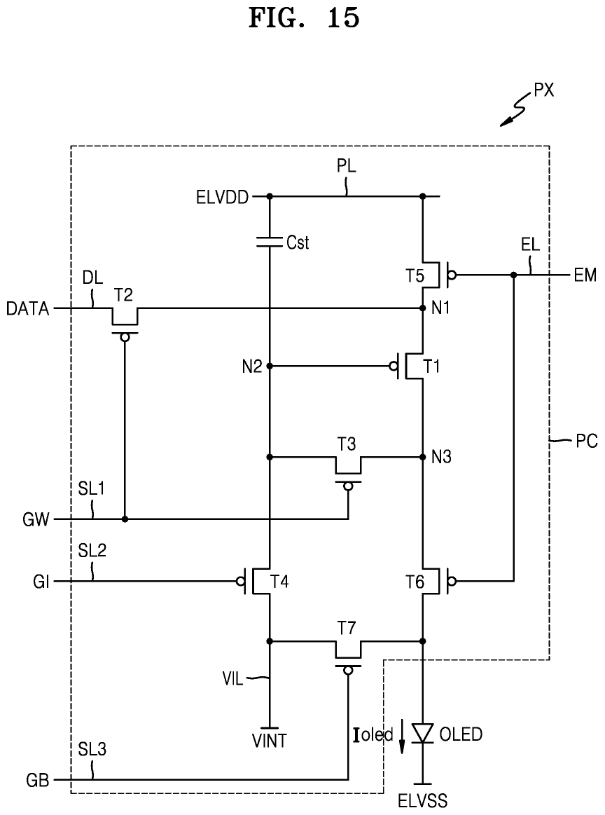

Referring to FIG. 15, in an alternative embodiment, the pixel circuit PC may include first to seventh transistors T1, T2, T3, T4, T5, T6, and T7. According to the type (N-type or P-type) of a transistor and/or an operating condition, a first terminal of the transistor may be a source electrode or a drain electrode, and a second terminal may be an electrode different from the first terminal. In an embodiment, for example, the first terminal may be a source electrode, and the second terminal may be a drain electrode.

The pixel circuit PC may be connected to a first scan line SL1 configured to transmit a first scan signal GW, a second scan line SL2 configured to transmit a second scan signal GI, a third scan line SL3 configured to transmit a third scan signal GB, an emission control line EL configured to transmit an emission control signal EM, a data line DL configured to transmit a data signal DATA, a driving voltage line PL configured to transmit a driving voltage ELVDD, and an initialization voltage line VIL configured to transmit an initialization voltage VINT. The pixel circuit PC may be connected to the organic light-emitting diode OLED as a display element.

The first transistor T1 may be connected between the driving voltage line PL and the organic light-emitting diode OLED. The first transistor T1 may be connected between a first node N1 and a third node N3. The first transistor T1 may be connected to the driving voltage line PL via the fifth transistor T5 and may be electrically connected to the organic light-emitting diode OLED via the sixth transistor T6. The first transistor T1 may include a gate electrode connected to a second node N2, a first terminal connected to the first node N1, and a second terminal connected to the third node N3. The driving voltage line PL may be configured to transmit the driving voltage ELVDD to the first transistor T1. The first transistor T1 functions as a driving transistor, and may receive the data signal DATA in response to a switching operation of the second transistor T2 and supply a driving current Ioled to the organic light-emitting diode OLED.

The second transistor T2 (data write transistor) may be connected between the data line DL and the first node N1. The second transistor T2 may be connected to the driving voltage line PL via the fifth transistor T5. The second transistor T2 may include a gate electrode connected to the first scan line SL1, a first terminal connected to the data line DL, and a second terminal connected to the first node N1. The second transistor T2 may be turned on in response to the first scan signal GW received through the first scan line SL1 and may be configured to perform a switching operation of transmitting the data signal DATA transmitted through the data line DL to the first node N1.

The third transistor T3 (compensation transistor) may be connected between the second node N2 and the third node N3. The third transistor T3 may be connected to the organic light-emitting diode OLED via the sixth transistor T6. The third transistor T3 may include a gate electrode connected to the first scan line SL1, a first terminal connected to the second node N2, and a second terminal connected to the third node N3. The third transistor T3 may be turned on in response to the first scan signal GW received through the first scan line SL1, and may diode-connect the first transistor T1, to compensate for a threshold voltage of the first transistor T1.

The fourth transistor T4 (first initialization transistor) may be connected between the second node N2 and the initialization voltage line VIL. The fourth transistor T4 may include a gate electrode connected to the second scan line SL2, a first terminal connected to the second node N2, and a second terminal connected to the initialization voltage line VIL. The fourth transistor T4 may be turned on in response to the second scan signal GI received though the second scan line SL2, and may be configured to transmit the initialization voltage VINT to the gate electrode of the first transistor T1, to initialize the gate electrode of the first transistor T1.

The fifth transistor T5 (first emission control transistor) may be connected between the driving voltage line PL and the first node N1. The sixth transistor T6 (second emission control transistor) may be connected between the third node N3 and the organic light-emitting diode OLED. The fifth transistor T5 may include a gate electrode connected to the emission control line EL, a first terminal connected to the driving voltage line PL, and a second terminal connected to the first node N1. The sixth transistor T6 may include a gate electrode connected to the emission control line EL, a first terminal connected to the third node N3, and a second terminal connected to a pixel electrode of the organic light-emitting diode OLED. The fifth transistor T5 and the sixth transistor T6 may be simultaneously turned on in response to the emission control signal EM received through the emission control line EL, such that a driving current flows through the organic light-emitting diode OLED.

The seventh transistor T7 (second initialization transistor) may be connected between the organic light-emitting diode OLED and the initialization voltage line VIL. The seventh transistor T7 may include a gate electrode connected to the third scan line SL3, a first terminal connected to the second terminal of the sixth transistor T6 and the pixel electrode of the organic light-emitting diode OLED, and a second terminal connected to the initialization voltage line VIL. The seventh transistor T7 may be turned on in response to the third scan signal GB received through the third scan line SL3, and may be configured to transmit the initialization voltage VINT to the pixel electrode of the organic light-emitting diode OLED, to initialize the pixel electrode of the organic light-emitting diode OLED.

The capacitor Cst may include a first electrode connected to the gate electrode of the first transistor T1 and a second electrode connected to the driving voltage line PL. The capacitor Cst may be configured to store and maintain a voltage corresponding to a difference between voltages at two ends of the driving voltage line PL and the gate electrode of the first transistor T1, such that a voltage applied to the gate electrode of the first transistor T1 may be maintained.

The organic light-emitting diode OLED may include a pixel electrode (first electrode or anode) and an opposite electrode (second electrode or cathode), and the opposite electrode may be configured to receive the common voltage ELVSS. The organic light-emitting diode OLED may be configured to receive the driving current from the first transistor T1 and emit light to display an image.

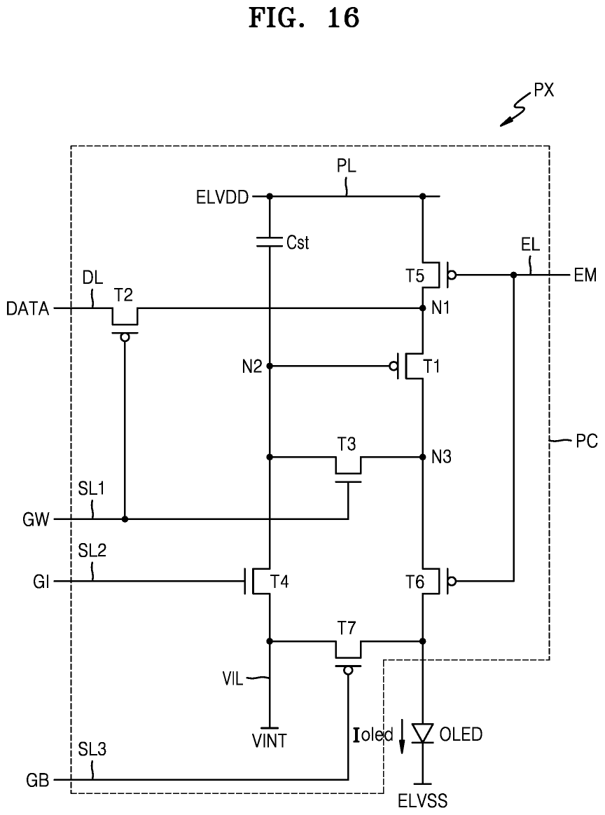

FIG. 15 illustrates an embodiment where the first to seventh transistors T1 to T7 are P-type transistors, but one or more embodiments are not limited thereto. In an alternative embodiment, for example, the first to seventh transistors T1 to T7 may be N-type transistors, or some of the first to seventh transistors T1 to T7 may be N-type transistors, and others thereof may be P-type transistors. FIG. 16 illustrates an alternative embodiment, the third transistor T3 and the fourth transistor T4 among the first to seventh transistors T1 to T7, are N-type transistors, and others may be P-type transistors. In such an embodiment, the third transistor T3 and the fourth transistor T4 may include a semiconductor layer including oxide, and the others may include a semiconductor layer including silicon.

In an embodiment, a display element may be an OLED as described above, but not being limited thereto. In an alternative embodiment, an inorganic light-emitting element or a quantum dot light-emitting element may be used as a display element.

In a case, where the substrate is bent in a bending area between a display area and a pad area of the substrate, the pad area may be positioned behind the display area. In this case, it may be difficult to reduce a lower peripheral area due to the area provided for the bending area, and defects such as disconnection may occur due to cracks caused by stress during bending of the substrate.

According to one or more embodiments of the invention, a conductive layer is embedded in the substrate, and a portion of the rear surface of the substrate is removed to expose a portion of the conductive layer, and accordingly, an IC or a film on which the IC is mounted may be electrically connected to the conductive layer. The conductive layer is electrically connected to signal lines on the substrate through a contact hole of insulating layers, and thus, the conductive layer may be configured to electrically connect the signal lines on the substrate to the IC on the rear surface of the substrate. According to one or more embodiments, the IC is disposed on the rear surface of the substrate without bending the substrate, to reduce the lower peripheral area, and thus, the area of a peripheral area recognized by a user may be further minimized (or substantially reduced), and defects due to the bending of the substrate may be effectively prevented.

Also, according to one or more embodiments, by embedding the conductive layer in the substrate, a shape and arrangement of the conductive layer, and the number and positions of pad areas may be allowed to be variously modified. According to one or more embodiments, depending on the shape and arrangement of the conductive layer, and the number and positions of pad areas, a width of the conductive layer, and the number and density of areas in which the conductive layer is in contact with a conductive line over the substrate may be changed to compensate for a voltage drop of a common voltage.

According to the one or more embodiments, the conductive layer is embedded in the substrate, and the IC and the signal lines on the substrate are electrically connected to each other by using the conductive layer, such that a dead area of the display apparatus may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate including a display area and a peripheral area surrounding the display area;
a display element arranged in the display area on the substrate;
a voltage supply line arranged in the peripheral area on the substrate, wherein the voltage supply line is electrically connected to a portion of a common electrode of the display element extending to the peripheral area; and
a conductive line embedded in the substrate and connected to the voltage supply line.

2. The display panel of claim 1, wherein the conductive line overlaps the voltage supply line and is electrically connected to the voltage supply line via a plurality of contact areas.

3. The display panel of claim 1, wherein the substrate includes:
a first base layer;
a second base layer on the first base layer; and
a barrier layer between the first base layer and the second base layer, wherein the barrier layer includes a first barrier layer and a second barrier layer,
wherein the conductive line is between the first barrier layer and the second barrier layer.

4. The display panel of claim 1, wherein
the conductive line surrounds the display area and is arranged in the peripheral area,
a pad area is defined in the peripheral area, and
a portion of the conductive line positioned in the pad area is connected to a flexible printed circuit board disposed on a rear surface of the substrate.

5. The display panel of claim 4, wherein
the conductive line includes a first portion and a second portion, wherein the second portion is positioned farther from the pad area than the first portion, and
a width of the second portion of the conductive line is greater than a width of the first portion.

6. The display panel of claim 4, wherein the conductive line includes a first portion and a second portion, wherein the second portion is positioned farther from the pad area than the first portion,
the conductive line is electrically connected to the voltage supply line via a plurality of contact areas, and
a number of the contact areas per unit length in the first portion of the conductive line is greater than a number of the contact areas per unit length in the second portion of the conductive line.

7. The display panel of claim 1, wherein the conductive line includes a first conductive line and a second conductive line, wherein the first conductive line surrounds the display area and is arranged in the peripheral area, and the second conductive line extends from the first conductive line to cross the display area,
a pad area is defined in the display area or the peripheral area, and
a portion of the second conductive line positioned in the pad area is connected to a flexible printed circuit board disposed on a rear surface of the substrate.

8. The display panel of claim 1, wherein the voltage supply line includes a first supply line and a second supply line, wherein the second supply line overlaps the first supply line and is in contact with the first supply line.

9. The display panel of claim 1, further comprising:
a first fan-out line arranged in the peripheral area on the substrate and connected to a data line of the display area; and
a second fan-out line disposed in a same layer as the conductive line and electrically connected to the first fan-out line.

10. The display panel of claim 9, wherein the substrate includes:
a first base layer;
a second base layer on the first base layer; and
a barrier layer between the first base layer and the second base layer, wherein the barrier layer includes a first barrier layer and a second barrier layer,
wherein the conductive line is between the first barrier layer and the second barrier layer,
an opening corresponding to a pad area is defined in the first barrier layer and the first base layer of the substrate, and
a portion of the second fan-out line positioned in the pad area is connected to the first fan-out line and a flexible printed circuit board disposed on a rear surface of the substrate.

11. A display apparatus comprising:
a display panel in which a display area and a peripheral area surrounding the display area are defined; and
an integrated circuit disposed on a rear surface of the display panel,
wherein the display panel includes:
a substrate;
a display element arranged in the display area on the substrate;
a voltage supply line arranged in the peripheral area on the substrate, wherein the voltage supply line is electrically connected to a portion of a common electrode of the display element extending to the peripheral area; and
a conductive line embedded in the substrate and connected to the voltage supply line.

12. The display apparatus of claim 11, wherein the conductive line overlaps the voltage supply line and is electrically connected to the voltage supply line via a plurality of contact areas.

13. The display apparatus of claim 11, wherein the substrate includes:
a first base layer;
a second base layer on the first base layer; and
a barrier layer between the first base layer and the second base layer, wherein the barrier layer includes a first barrier layer and a second barrier layer,
wherein the conductive line is between the first barrier layer and the second barrier layer.

14. The display apparatus of claim 13, wherein
an opening corresponding to a pad area is defined in the first base layer of the substrate, and
the integrated circuit is mounted on a flexible printed circuit board, a portion of which is disposed in the opening.

15. The display apparatus of claim 11, wherein
the conductive line surrounds the display area and is arranged in the peripheral area,
a pad area is defined in the peripheral area,
a trench is defined in the rear surface of the substrate, wherein the trench exposes a portion of the conductive line in the pad area, and
the portion of the conductive line is connected to a portion of a flexible printed circuit board disposed in the trench.

16. The display apparatus of claim 15, wherein the conductive line includes a first portion and a second portion, wherein the second portion is positioned farther from the pad area than the first portion, and
a width of the second portion of the conductive line is greater than a width of the first portion.

17. The display apparatus of claim 15, wherein the conductive line includes a first portion and a second portion, wherein the second portion is positioned farther from the pad area than the first portion,
the conductive line is electrically connected to the voltage supply line via a plurality of contact areas, and
a number of the contact area per unit length in the first portion of the conductive line is greater than a number of the contact areas per unit length in the second portion of the conductive line.

18. The display apparatus of claim 11, wherein the conductive line includes a first conductive line and a second conductive line, wherein the first conductive line surrounds the display area and is arranged in the peripheral area, and the second conductive line extends from the first conductive line to cross the display area,
a pad area is defined in the display area or the peripheral area,
a trench is defined in the rear surface of the substrate, wherein the trench exposes a portion of the second conductive line arranged in the pad area, and
the portion of the second conductive line is connected to a portion of a flexible printed circuit board disposed in the trench.

19. The display apparatus of claim 11, wherein the voltage supply line includes a first supply line and a second supply line, wherein the second supply line overlaps the first supply line and is in contact with the first supply line.

20. The display apparatus of claim 11, further comprising:
a first fan-out line arranged in the peripheral area on the substrate and connected to a data line of the display area; and
a second fan-out line disposed in a same layer as the conductive line and electrically connected to the first fan-out line.
